(19) United States
(12) Patent Application Publication
(10) Pub. No.: US 2006/0087039 A1
(43) Pub. Date: Apr. 27, 2006

(54) UBM STRUCTURE FOR IMPROVING RELIABILITY AND PERFORMANCE

(75) Inventors: CHIU SUNG CHENG, JHUBEI CITY (TW); SHIH-MING CHEN, JHUNAN TOWNSHIP (TW); H.M. YU, HSINCHU (TW); KUO-WEI LIN, SHINCHU COUNTY (TW); LI-HSIN TSENG, TAICHUNG CITY (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., HSIN-CHU (TW)

(21) Appl. No.: 10/904,096

(22) Filed: Oct. 22, 2004

(51) Int. Cl. H01L 23/48; H01L 21/44

(52) U.S. Cl. 257/750; 438/612; 438/614; 257/762; 257/766; 257/779

(57) ABSTRACT

A novel under-bump metallization (UBM) structure for providing electrical communication is described. The UBM structure includes a plurality of metallic layers, which are deposited onto a bonding pad of a semiconductor device, such as a semiconductor chip. The UBM structure may be provided as an interface between the bonding pad and a solder bump deposited over the UBM structure. In one example, the UBM structure includes layers of nickel and copper in which nickel is the upper layer in contact with the solder bump and copper is the lower layer in contact with the bonding pad. The nickel layer is formed to include a downwardly depending perimeter portion, which serves as a cover to the copper layer of the UBM structure. Accordingly, the copper layer is shielded from contact with the solder material during the reflow process, thereby avoiding undesirable reactions between the copper and solder.

### TECHNICAL FIELD

Disclosed embodiments herein relate generally to semiconductor wafer processing, and more particularly to improved under-bump metallization (UBM) structures and associated methods for improving reliability and performance of such UBM structures.

### BACKGROUND

UBM structures are often utilized during semiconductor manufacturing processes. Semiconductor manufacturing processes generally begin with processes associated with fabricating a semiconductor wafer such as layering, patterning, doping, and heat treatments. Once fabricated, semiconductor wafers undergo additional processes associated with testing, packaging, and assembling semiconductor IC chips obtained from the wafers. Semiconductor manufacturing processes are continually being refined, modified, and improved in light of breakthroughs in semiconductor technology. One such technology that has continued to gain increased acceptance is “flip chip” technology, which refers to microelectronic assemblies in which direct electrical connections between face down, or flipped, chip components and outside components (e.g. substrates) are achieved through conductive bump or bonding pads formed on the chip.

Bonding pads in flip chips are typically manufactured to include a final metal layer, such as aluminum, to facilitate electrical communication from the IC chip. Flip chips are also manufactured to include solder bumps, which are deposited onto the bonding pads of such chips to physically and electrically connect the bonding pads with electrode terminals provided on packaging such as ceramic substrates, printed circuit boards, or carriers. Solder bumps are typically formed of a metal alloy such as a lead-tin alloy, and are often applied to semiconductor wafers prior to separation into individual semiconductor chips.

Solder bumps, however, are generally not applied directly to the bonding pads of the semiconductor wafer. It has been found that the direct application of solder bump material to the semiconductor wafer yields poor electrical conduction, due largely to the rapid oxidation of the final metal layer (e.g. aluminum) upon exposure to air. Moreover, aluminum has been found to be neither particularly wettable nor bondable with most solders. Accordingly, UBM structures and associated techniques have been developed to provide a low resistance electrical connection between the solder bump and the underlying bonding pad, while withstanding the various stresses associated with semiconductor applications.

UBM structures generally include one or more metallic layers, such as layers of titanium and/or copper, deposited over the bonding pads of IC chips. In practice, solder is typically deposited over a UBM structure, and then heated via a reflow process to form a generally spherical solder bump. It has been found that prior art UBM structures tend to experience poor reliability and performance when solder material comes in contact with copper of the UBM structure during the solder bump formation process. More particularly, the interface of copper with solder during the soldering process may generate a variety of interfacial reactions, such as dissolution of copper into the solder, formation of intermetallic compounds, and oxidation of the copper layer. These reactions are generally undesirable as they weaken the bond between the solder bump and the bonding pad of the chip, thereby leading to premature failure of the chip. For example, some chips in which these reactions have been observed have been found to fail after 1000 hours of high temperature storage.

FIG. 1 illustrates an exemplary prior art solder bump arrangement in which a solder bump 10 has been formed over an aluminum bonding pad 12 of an IC chip 14. A plurality of UBM layers 16A, 16B have been formed between the resulting solder bump 10 and the bonding pad 12. In this example, the UBM layer 16A is a layer of copper and the UBM layer 16B is some metallic layer other than copper. The UBM layers 16A, 16B are formed such that their perimeter edges 18A, 18B, respectively, are substantially flush with one another and are exposed to outside elements. A passivation layer 22 and a polyimide layer 24 have also been formed over the IC chip 14.

One problem associated with this prior art solder bump arrangement relates to the wetting behavior of the solder and the UBM layers. In particular, it is generally desired that the solder wet only an upper surface 26 of the UBM layer adjacent to the solder (e.g. contact layer 16B) during the reflow process, thereby confining the solder bump 10, and therefore solder material, to the upper surface 26 of UBM layer 16B. During solder reflow, surface tension effects cause the solder to take a spherical shape, thereby resulting in the solder bump 10. In theory, such surface tension effects would confine the solder to the upper surface 26 of UBM layer 16B as desired. However, in practice, it has been found that the mechanical integrity of the joint formed between the solder bump 10 and the UBM joint layer 16B as well as the mechanical integrity of the underlying UBM layers, such as UBM layer 16A, can be compromised by the phenomenon of solder spill-over where reflowing solder flows along and wets the exposed perimeter edges 18A, 18B of the UBM layers 16A, 16B, respectively. As a result, the copper UBM layer 16A underlying the wettable UBM layer 16B may be weakened due to the above-described reactions associated with the interface of copper and solder. Such weakening adversely affects the reliability and performance of the UBM structure and the associated IC chip.

Therefore, what is needed is an improved UBM structure and associated technique, which when employed, improves reliability and performance of the UBM structure and associated device incorporating the UBM structure by overcoming the deficiencies of the prior art.

### BRIEF SUMMARY

A novel UBM structure for improving the reliability and performance of the UBM structure and associated device is described. The UBM structure comprises a plurality of metallic layers, which are deposited onto an electrically conductive element, such as a bonding pad of a semiconductor device. The UBM structure is provided as an interface between the bonding pad and another electrically conductive element, such as solder material deposited over the UBM structure. In one embodiment, the UBM structure includes layers of nickel and copper in which nickel is the upper layer in contact with the solder material. The nickel layer is formed to include a downwardly depending perimeter portion, which serves as a cover to the copper layer of the UBM structure. Accordingly, the copper layer is shielded from contact with the solder material during a reflow process, thereby avoiding undesirable reactions between the copper and solder.

Related methods for forming a UBM structure having at least one copper layer are described. In one embodiment, the method for forming a UBM structure includes depositing varying metallic layers onto an electrically conductive element, such as a bonding pod of a semiconductor device. For example, layers of nickel and copper may be applied to the bonding pad. Another electrically conductive element, such as solder material, is then deposited onto the metallic layers. The nickel layer is deposited as the upper, or contact, layer and the method includes forming a downwardly depending perimeter portion of the nickel layer to cover the copper layer, and thereby shield the copper layer from solder material during a solder reflow process. Accordingly, practicing the method of the present disclosure avoids undesirable reactions between the copper and solder.

### BRIEF DESCRIPTION OF THE DRAWINGS

Reference is now made to the following descriptions taken in conjunction with the accompanying drawings.

FIG. 1 illustrates an elevational view of a semiconductor chip having undergone a prior art solder bump formation process.

FIG. 2 illustrates a general block diagram of one embodiment of a process associated with manufacturing semiconductor devices; and

FIGS. 3A-3E illustrate elevational views of an exemplary process for forming a UBM structure and associated solder bump on an individual chip of the semiconductor wafer.

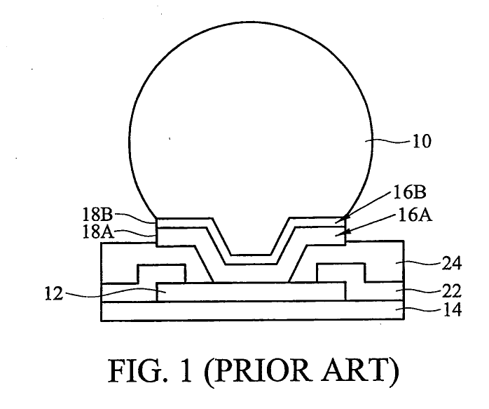

### DETAILED DESCRIPTION

UBM structures may be utilized in any arrangement requiring bonding between electrically conductive components. By way of example, UBM structures are often utilized in the manufacture of semiconductor devices. Although this disclosure describes unique UBM structures in the context of implementation into semiconductor devices, it is contemplated that the UBM structures of the present disclosure may be incorporated into devices other than semiconductor devices.

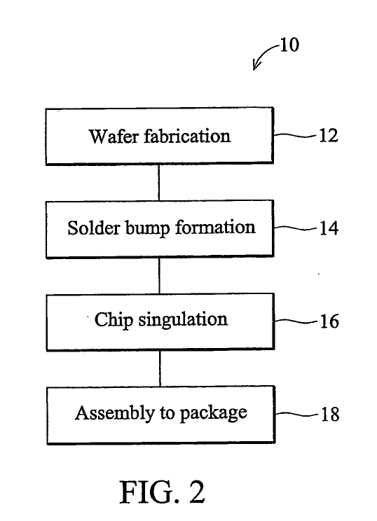

FIG. 2 is a block diagram illustrating an exemplary semiconductor manufacturing process 10 associated with producing chips for use in semiconductor applications. The process 10 includes wafer fabrication 12, which generally involves layering, patterning, doping, and applying heat treatments to a silicon wafer. The process 10 further includes forming solder bumps 14 on the fabricated wafer. The solder bumps generally facilitate electrical and mechanical connection between chip devices singulated from the fabricated wafer and a desired packaging substrate as will be further described. The fabricated wafer is then cut into singulated chips 16 each comprising an entire integrated circuit. After singulation, the chips are assembled 18 with desired packaging to complete the manufacturing process.

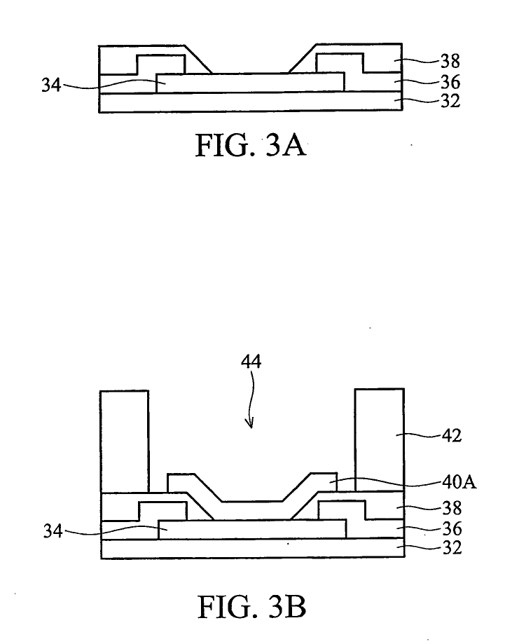

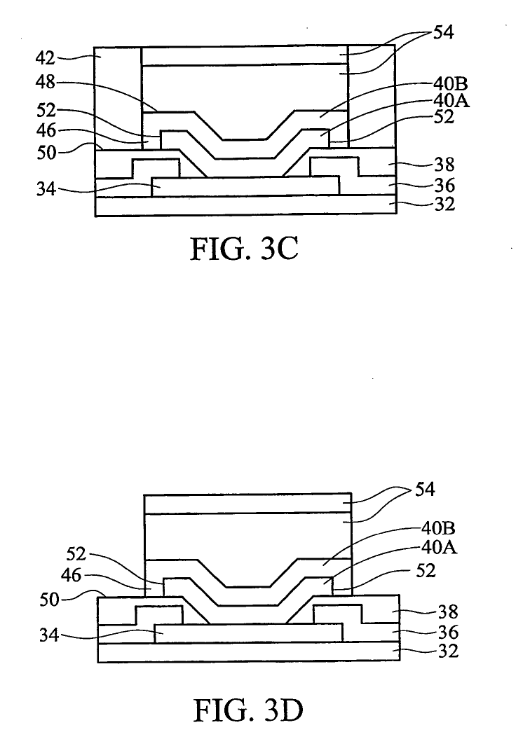

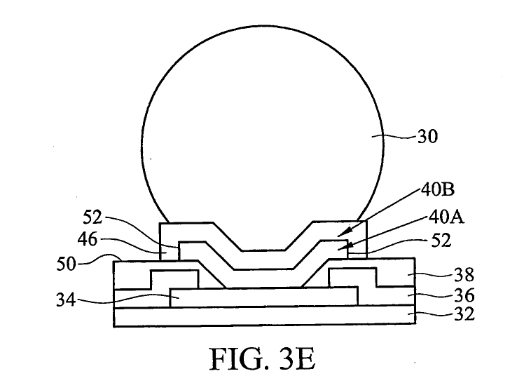

Each of the above-described processes may be carried out in a variety of ways. The following disclosure relates to particular manners for carrying out the solder bump formation process 14, and more particularly, ways for forming a UBM structure associated with the solder bump formation process 14. FIGS. 3A-3E illustrate one exemplary process for forming a solder bump 30 (FIG. 3E) on a portion of a semiconductor chip 32. The solder bump 30 may be formed of a metallic alloy such as a lead-tin alloy. In some embodiments, the solder bump 30 may be formed as part of a larger C4 process (Controlled-Collapse Chip Connection), which connects semiconductor chips, such as chip 32, to substrates in electronic packages.

The chip 32 is manufactured to include a plurality of bonding pads 34, one of which is shown in FIGS. 3A-3E. The bonding pad 34 is a source of electrical communication from the chip 32, and typically comprises copper (Cu) or aluminum (Al) with patterned levels of interconnecting metal lines. For example, signal lines and power/ground lines can be connected to the bonding pad 34. The bonding pad 34 may be formed in a variety of manners such as through vapor deposition.

After the bonding pad 34 is formed, a passivation layer 36 is formed over the semiconductor chip 32 surface excluding a portion overlying the bonding pad. The passivation layer 36 may be vapor deposited over the chip 32 to generally insulate and protect the surface of the chip 32 from moisture and other contaminants and also from mechanical damage during assembling of the chip. The passivation layer 36 may be formed of a variety of materials, such as silicon oxide/silicon nitride (SiO₂/Si₃N₄) or phosphorous doped silicon dioxide. Various types of photosensitive polyimides may also be deposited as a polyimide layer 38 over the passivation layer 36 to further protect the chip 32.

Referring to FIG. 3B, a first under-bump metallization (UBM) layer 40A may then be deposited over the bonding pad 34. UBM layers are typically formed over the bonding pad 34 to allow for better bonding and wetting of the solder material to an uppermost UBM layer adjacent to the solder material, and for protection of the bonding pad 34 by a lowermost UBM layer, such as UBM layer 40A. In one example, the UBM layer 40A may be of from about 2-5 microns in height and may be formed of copper.

A layer of photoresist 42 is additionally formed to terminate at the polyimide layer 38 in a horizontally spaced relation from the UBM layer 40A. The photoresist layer 42 is typically from about 10 to about 25 microns in height. As shown in FIG. 3B, the photoresist layer 42 is photolithographically patterned and developed to form an opening 44 above the bonding pad 34 to expose a UBM layer, e.g., UBM layer 40A.

Referring to FIG. 3C, an additional UBM layer, such as UBM layer 40B, may be formed within the mask opening 44 by, for example, an electroplating process or vapor deposition process. Layer 40B may be of from about 2-3 microns in height and may be formed of nickel. The spacing between the photoresist layer 42 and the UBM layer 40A allows a portion of the UBM layer 40B (downwardly depending perimeter portion 46 in FIG. 3C) to form between the copper UBM layer 40A and the photoresist layer 42. As a result, the UBM layer 40B provides a contact surface 48 for contacting the resulting solder bump 30, while also having a downwardly depending perimeter portion 46 extending from the contact surface 48 to an upper surface 50 of the polyimide layer 38. Accordingly, the perimeter portion 46 of UBM layer 40B covers a perimeter edge 52 (lateral edges 52 in the cross-sectional depiction of FIGS. 3C and 3D) of the copper UBM layer 40A, thereby shielding the copper layer from the outside (ambient) environment as will be further described. In one example, the perimeter portion 46 is about 2-5 microns in width.

A column of solder material 54 may either be deposited in layers, for example, a layer of lead followed by a layer of tin, where the solder material layers are later formed into a homogeneous solder bump during a reflow (e.g., temporary melting) process for solder material. In other embodiments, the solder material may be deposited as a homogeneous solder material by vapor deposition or electroplating onto a “seed” layer.

Referring to FIG. 3D, after removal of the photoresist layer 42, the solder column 54 is temporarily heated to a melting point in a reflow process to form the solder bump 30 over the UBM layer 40B, as shown in FIG. 3E. Completion of the reflow process results in the formation of the homogeneous lead/tin solder bump 30. In some embodiments, the solder bump 30 is a high lead alloy having composition ratios (indicating weight percent) of 95 Pb/5 Sn (95/5) or 90 Pb/10 Sn (90/10) with melting temperatures in excess of 300° C. or eutectic 63 Pb/37 Sn (63/37) with a melting temperature of 183° C. Generally speaking, the resulting solder bump 30 is composed of a homogeneous material and has a well-defined melting temperature. The high melting Pb/Sn alloys are reliable bump metallurgies that are particularly resistant to material fatigue.

The reflow process is typically used to melt the solder column 54 such that surface tension effects create a substantially spherical solder bump 30 overlying the bonding pad 34. However, it has been found that some of the solder material of the solder column 54 tends to spill over the side of the contact UBM layer (e.g. contact layer 40B) during the reflow process. By employing the UBM structure of the present disclosure, such solder material is shielded from contact with the copper UBM layer 40A via the downwardly depending perimeter portion 46 of the contact UBM layer 40B. Accordingly, the detrimental effects associated with contact between solder material and copper of the copper UBM layer 40A can be effectively avoided.

The above-described process for forming the solder bump 30 is merely exemplary. Accordingly, the solder bump 30 may be formed in a variety of other manners, including processes other than photoresist processes, without departing from the scope of the disclosure. Also, FIGS. 3A-3E are schematic depictions of the chip 32 and associated structure, and therefore, should not be construed to limit the such structure to any particular geometric orientation. For example, the downwardly depending portion 46 of the UBM structure 40B is shown as extending in a substantially orthogonal direction relative to the upper surface 48 of the UBM layer 40B. However, in practice, the downwardly depending portion 46 may extend partially inwardly (e.g. towards a center portion of the bonding pad 34) and underneath the UBM layer 40A, thereby providing a geometric orientation different than that of the schematic depictions of FIGS. 3A-3E. Additionally, the geometric orientations of the UBM layers 40A, 40B and the passivation and polyimide layers 36 and 38, respectively, may also be altered to have different shapes. Accordingly, these layers may take flat (uniform in cross-section) or non-flat (non-uniform in cross-section) configurations.

Still further, although the UBM layer 40B is described as being formed of nickel, various other materials may be used in the formation of UBM layer 40B. Moreover, the overall chip/bump structure has been described as having certain types of layers. However, layers such as the passivation layer 36 and the polyimide layer 38 may be altered or even removed without departing from the scope of the disclosure. Additional UBM layers may be provided so long as the copper UBM layer 40A is shielded from the outside environment. Furthermore, although described as a perimeter portion, the downwardly depending perimeter portion 46 may be associated with a layer having a portion extending laterally beyond the perimeter portion 46. Accordingly, it is contemplated that the perimeter portion 46 may not be the outermost portion of the associated UBM layer 40B.

While various UBM structures and related methods for forming UBM structures during the solder bump formation process according to the principles disclosed herein have been described above, it should be understood that they have been presented by way of example only, and not limitation. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Brief Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

1. A UBM structure for disposal onto an electrically conductive element, comprising:
a first metallic layer disposed over the electrically conductive element, the first metallic layer being formed of copper and having a perimeter edge; and
a second metallic layer disposed over the first metallic layer, the second metallic layer being spaced from the electrically conductive element via the first metallic layer along a portion of the second metallic layer, the second metallic layer further having a perimeter portion covering the perimeter edge of the first metallic layer, thereby shielding the first metallic layer from ambient surroundings.

2. The UBM structure of claim 1 wherein the second metallic layer is formed of nickel.

3. The UBM structure of claim 1 further comprising an additional metallic layer disposed adjacent to and in contact with the second metallic layer.

4. The UBM structure of claim 1 wherein the electrically conductive element and the UBM structure are associated with a semiconductor device.

5. The UBM structure of claim 4 wherein the electrically conductive element is a bonding pad formed on a semiconductor chip of the semiconductor device.

6. The UBM structure of claim 5 wherein the semiconductor device further comprises a passivation layer disposed adjacent to and in contact with each of the semiconductor chip and die bonding pad.

7. The UBM structure of claim 6 wherein the perimeter portion of the second metallic layer terminates at the passivation layer.

8. The UBM structure of claim 6 wherein the semiconductor device further comprises a polyimide layer disposed adjacent to and in contact with the passivation layer, the bonding pad, the first metallic layer, and the second metallic layer.

9. The UBM structure of claim 8 wherein the perimeter portion of the second metallic layer terminates at the polyimide layer.

10. The UBM structure of claim 1 wherein the first metallic layer is about 2-5 microns in height.

11. The UBM structure of claim 1 wherein the second metallic layer is about 2-3 microns in height.

12. The UBM structure of claim 1 wherein the perimeter portion is about 2-5 microns in width.

13. A semiconductor device, comprising:
a semiconductor chip having a bonding pad formed on a surface thereof; and
a UBM structure formed over the bonding pad, the UBM structure comprising a first metallic layer formed of copper disposed adjacent to and in contact with the bonding pad, the first metallic layer having a perimeter edge, the UBM structure further comprising a second metallic layer disposed adjacent to and in contact with the first metallic layer, the second metallic layer having a perimeter portion extending beyond the perimeter edge of the first metallic layer, the perimeter portion extending along the perimeter edge of the first metallic layer and terminating at another portion of the semiconductor device.

14. The semiconductor device of claim 13 wherein the another portion of the semiconductor device is a polyimide layer.

15. The semiconductor device of claim 13 wherein the another portion of the semiconductor device is a passivation layer.

16. The semiconductor device of claim 13 wherein the second metallic layer is formed of nickel.

17. The semiconductor device of claim 13 further comprising an additional metallic layer disposed adjacent to and in contact with the second metallic layer.

18. The semiconductor device of claim 13 further comprising a solder bump formed over the second metallic layer, wherein electrical communication is established from the bonding pad, through the UBM structure, and to the solder bump.

19. The semiconductor device of claim 13 wherein the first metallic layer is about 2-5 microns in height.

20. The semiconductor device of claim 13 wherein the second metallic layer is about 2-3 microns in height.

21. The semiconductor device of claim 13 wherein the perimeter portion is about 2-5 microns in width.

22. A UBM structure for establishing electrical communication between a bonding pad of a semiconductor chip and a solder bump formed over the bonding pad, the UBM structure, comprising:
a lower metallic layer deposited over the bonding pad, the lower metallic layer being formed of copper and having a first perimeter; and
an upper metallic layer deposited over the lower metallic layer and providing a contact surface for the solder bump, the upper metallic layer having a second perimeter extending beyond the first perimeter, and a downwardly depending perimeter portion which shields the lower metallic layer from ambient surroundings.

23. The BM structure of claim 22 wherein the downwardly depending perimeter portion terminates at a polyimide layer formed over the semiconductor chip.

24. The UBM structure of claim 22 further comprising an additional metallic layer disposed adjacent to and in contact with one of the lower and upper metallic layers.

25. The UBM structure of claim 22 wherein the upper metallic layer is comprised of nickel.

26. The UBM structure of claim 22 wherein the lower metallic layer is about 2-5 microns in height.

27. The UBM structure of claim 22 wherein the upper metallic layer is about 2-3 microns in height.

28. The UBM structure of claim 22 wherein the perimeter portion is about 2-5 microns in width.

29. A method for forming a semiconductor device, comprising:
providing a bonding pad associated with the semiconductor device;
depositing a first metallic layer over the bonding pad, the first metallic layer being formed of copper and having a finite size defined by a perimeter edge;
depositing a second metallic layer over the first metallic layer, the second metallic layer having a perimeter portion extending beyond the perimeter edge of the first metallic layer, the perimeter portion shielding the first metallic layer from ambient surroundings; and
forming a solder bump over the bonding pad and in contact with the second metallic layer, whereby the first metallic layer is shielded from solder material during solder bump formation via the second metallic layer.

30. The method of claim 29 further comprising depositing a passivation layer adjacent to the bonding pad.

31. The method of claim 30 wherein the perimeter portion of the second metallic layer terminates at the passivation layer.

32. The method of claim 30 further comprising depositing a polyimide layer over and in contact with the passivation layer.

33. The method of claim 32 wherein the perimeter portion of the second metallic layer terminates at the polyimide layer.

34. The method of claim 29 wherein the second metallic layer is formed of nickel.
